(19) United States
(12) Patent Application Publication
(10) Pub. No.: US 2014/0175498 A1
(43) Pub. Date: Jun. 26, 2014

(54) LED CHIP UNIT WITH CURRENT BAFFLE

(71) Applicant: HON HAI PRECISION INDUSTRY CO., LTD., New Taipei (TW)

(72) Inventor: CHIH-CHEN LAI, New Taipei (TW)

(21) Appl. No.: 13/936,359

(22) Filed: Jul. 8, 2013

(30) Foreign Application Priority Data
Dec. 21, 2012 (TW) 101149094

(51) Int. Cl. H01L 33/62

(52) U.S. Cl. CPC H01L 33/62
USPC 257/99

(57) ABSTRACT

An LED chip unit includes a base and a chip mounted on the base. The chip includes a substrate, a first semiconductor layer, a light emitting layer, a second semiconductor layer and an electrode. The base forms multiple conductive posts and current baffles therein. Widths of the current baffles gradually decrease from a central portion of the chip towards two lateral portions of the chip.

### BACKGROUND

1. Technical Field

The disclosure generally relates to an light emitting diode (LED) chip unit, and more particularly, to an LED chip unit with current baffles.

2. Description of Related Art

Nowadays light emitting diodes (LEDs) are used widely in various applications for illumination. There are two types of LED chips available in typical LEDs, a lateral LED chip and a vertical LED chip. The vertical LED chip generally includes a conductive substrate, an N-type semiconductor layer formed on the substrate, a light emitting layer formed on the N-type semiconductor layer, a p-type semiconductor layer formed on the light emitting layer, and a P-type electrode formed on the P-type semiconductor layer. In operation, current flows from the P-type electrode to the substrate, thereby activating the light emitting layer to emit light.

However, the P-type electrode has a smaller surface area less than that of the P-type semiconductor layer, and only covers a central area of the P-type semiconductor layer. The current flowing through the chip is prone to converge at a central portion of the chip corresponding to the P-type electrode. Thus, more current flows through the central portion of the chip than two lateral portions of the chip. As a result, the chip cannot emit light with uniform intensity due to uneven distribution of the current within the chip.

What is needed, therefore, is an LED chip unit with current baffles which can address the shortcomings as described above.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the various views.

FIG. 1 is a cross section of an LED chip unit in accordance with a first embodiment of the present disclosure.

FIG. 2 is a cross section of an LED chip unit in accordance with a second embodiment of the present disclosure.

FIG. 3 is a cross section of an LED chip unit in accordance with a third embodiment of the present disclosure.

FIG. 4 is a cross section of an LED chip unit in accordance with a fourth embodiment of the present disclosure.

### DETAILED DESCRIPTION

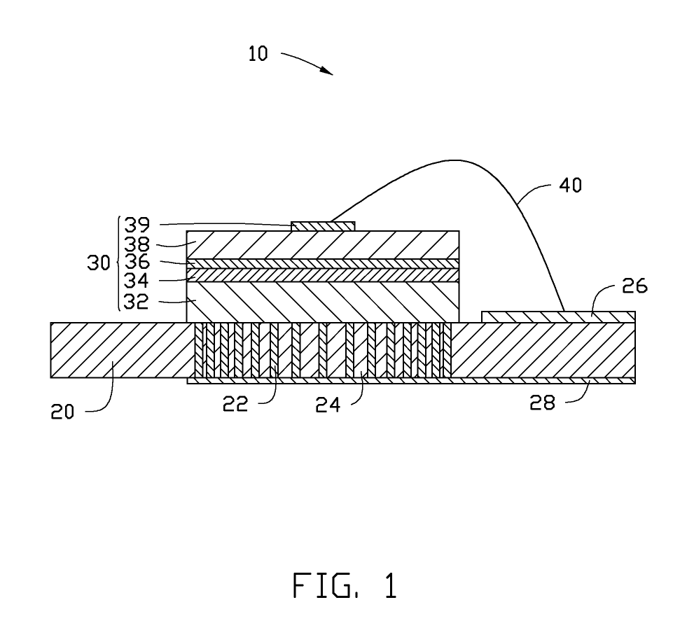

Referring to FIG. 1, an LED (light emitting diode) chip unit 10 in accordance with a first embodiment of the present disclosure is shown. The LED chip unit 10 includes a base 20 and a chip 30 mounted on the base 20.

The chip 30 includes a substrate 32, a first semiconductor layer 34, a light emitting layer 36, a second semiconductor layer 38 and an electrode 39. The substrate 32 may be made of electrical-conductive material such as Si, SiC, Al, Cu or the like. The first semiconductor layer 34 may be an N-type semiconductor layer made of GaN, InGaN, AlInGaN or other suitable materials. The second semiconductor layer 38 may be a P-type semiconductor layer made of GaN, InGaN, AlInGaN or other suitable materials. The light emitting layer 36 may be a multiple quantum wall layer made of GaN, InGaN, AlInGaN or other suitable materials. The electrode 39 may be made of metal such as Au, Ni or alloy thereof. The electrode 39 has an area less than that of the second semiconductor layer 38. The electrode 39 is formed on a central area of a top face of the second semiconductor layer 38.

The base 20 is made of heat-conducive and electrical-insulative material such as ceramic. The base 20 has a plurality of electrical-conductive posts 22 embedded therein. The posts 22 may be made of metal such as Al, Cu, Ag, Au or the like. The posts 22 are parallel to each other. Each post 22 extends from a top face to a bottom face of the base 20. In this embodiment, the posts 22 have the same width and length. The posts 22 are arranged more densely at two lateral portions of the chip 30 than at a central portion of the chip 30. A part of the base 20 between the posts 22 form a plurality of current baffles 24. The current baffles 24 are spaced from each other by the posts 22. The current baffles 24 are alternate with the posts 22. Each current baffle 24 also extends from the top face to the bottom face of the base 20. In this embodiment, the current baffles 24 are arranged in the same density. Widths of the current baffles 24 gradually decrease from the central portion of the chip 30 towards the two lateral portions of the chip 30.

A first electrical pad 26 is formed on the top face of the base 20, and a second electrical pad 28 is formed on the bottom face of the base 20. Both of the first electrode pad 26 and the second electrical pad 28 are made of metal such as Al, Cu, Ag, Au or the like. The first electrical pad 26 is located adjacent to the chip 30. A wire 40 electrically connects the first electrical pad 26 with the electrode 39 of the chip 30. The second electrical pad 28 covers and directly connects the posts 55. Therefore, the chip 30 is electrically connected to the base 20 via the first electrical pad 26 and the second electrical pad 28. Current can be input from an external power source to the chip 30 through the base 20.

The uneven distribution of the posts 22 and the different widths of the current baffles 24 can force the current to spread from the central portion of the chip 30 to the two lateral portions of the chip 30, thereby uniformly flowing through the chip 30. Therefore, the chip 30 can emit uniform light due to the uniformly distributed current.

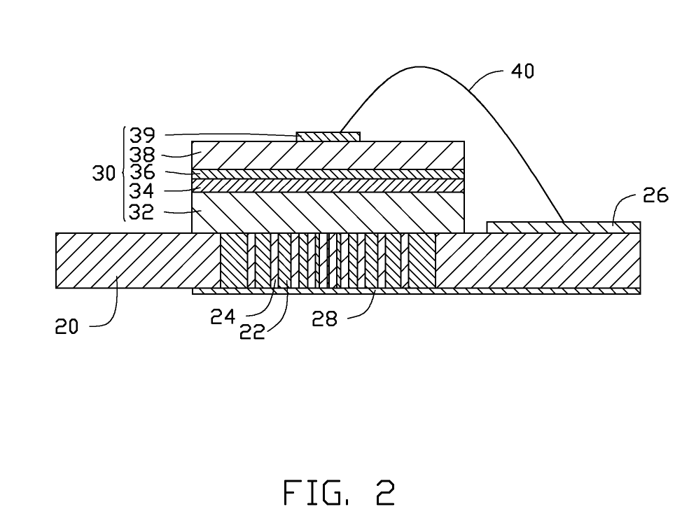

Alternatively, as shown in FIG. 2, the posts 22 can also be arranged in the same density with different widths. The widths of the posts 22 gradually increase from the central portion of the chip 30 towards the two lateral portions of the chip 30. The current baffles 24 have the same width and different density according to variation of the posts 22. The distribution density of the current baffles 24 at the central portion of the chip 30 is larger than at the two lateral portions of the chip 30.

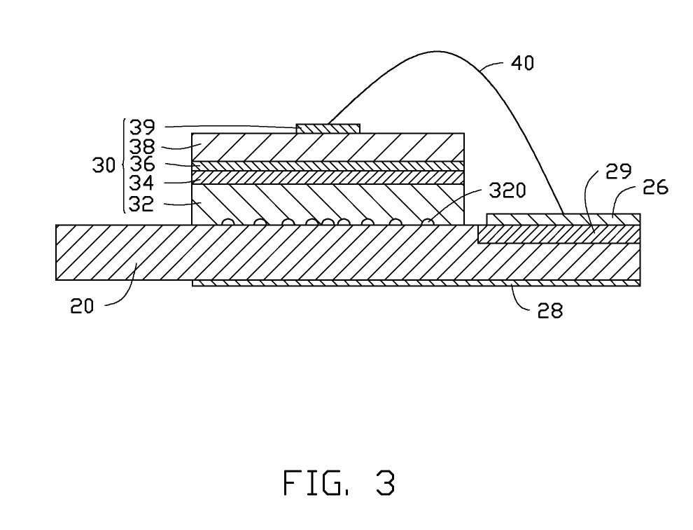

FIG. 3 shows an LED chip unit 10 different from that shown in FIGS. 1-2. The LED chip unit 10 also includes a chip 30 and a base 20 supporting the chip 30. The chip 30 have the same configuration with that shown in FIGS. 1-2, also including a substrate 32, a first semiconductor layer 34, a light emitting layer 36, a second semiconductor layer 38 and an electrode 39. However, the chip 30 directly forms a plurality of current baffles 320 in a bottom face of the substrate 32. In this embodiment, the current baffles 320 are curved depressions. Each depression is void with air contained therein. The depressions have the same sizes with different distribution densities. In detail, the distribution density of the depressions at a central portion of the chip 30 is larger than at two lateral portions of the chip 30.

The base 20 is made of heat-conductive and electrical-conductive material such as metal. A first electrical pad 26 is formed on a top of the base 20, and a second electrical pad 28 is formed on a bottom of the base 20. An insulative layer 29 is formed between the base 20 and the first electrical pad 26. The first electrical pad 26 is insulated from the base 20 by the insulative layer 29. The first electrical pad 26 has a thickness less than that of the insulative layer 29. Current can directly flow through the base 20 after passing through the chip 30. The depressions can also enable the current to uniformly flow through the chip 30 as the current baffles 24 shown in FIGS. 1-2.

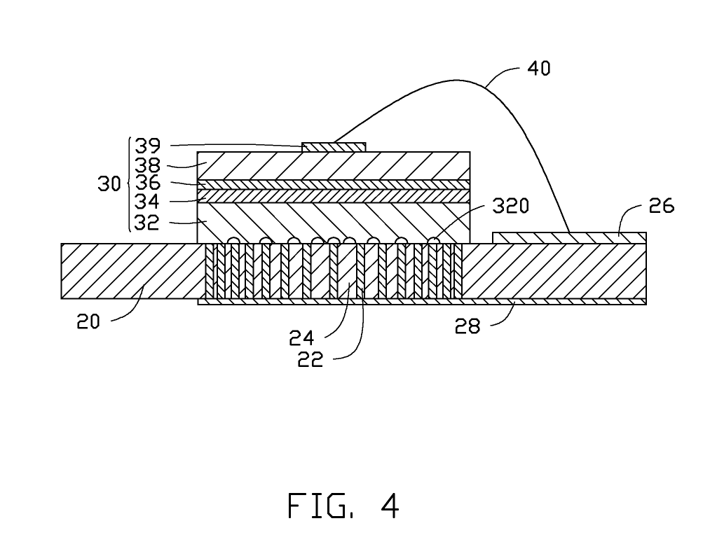

Furthermore, also referring to FIG. 4, the hollow current baffles 320 shown in FIG. 3 can be used in combination with the solid current baffles 24 shown in FIGS. 1-2. The two type current baffles 24, 320 can facilitate more uniform distribution of the current within the chip 30.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. Alight emitting diode (LED) chip unit comprising:
a chip comprising a substrate, a first semiconductor layer, a light emitting layer, a second semiconductor layer and an electrode;
a base supporting the chip; and
a plurality of current baffles formed at an interface of the chip and the base, wherein the interface comprises a first location corresponding to the electrode and a second location away from the first location, and sizes or densities, or both, of the current baffles decrease from the first location towards the second location.

2. The LED chip unit of claim 1, wherein the first location is a central portion of the chip, and the second location is a periphery portion of the chip.

3. The LED chip unit of claim 1, wherein the current baffles are more densely distributed at the first location than at the second location.

4. The LED chip unit of claim 1, wherein the current baffles are wider at the first location than at the second location.

5. The LED chip unit of claim 1, wherein the base comprises a first electrical pad formed on a top face thereof and a second electrical pad formed on a bottom face thereof.

6. The LED chip unit of claim 5, wherein the first electrical pad is located adjacent to the chip.

7. The LED chip unit of claim 5, wherein the electrode is electrically connected to the first electrical pad via a wire.

8. The LED chip unit of claim 5, wherein the current baffles are solid.

9. The LED chip unit of claim 8, wherein the current baffles are completely embedded within the base.

10. The LED chip unit of claim 8, wherein the base comprises a plurality of electrical-conductive posts embedded/surrounded by an electrical-insulative material, the plurality of electrical conductive posts extend from the top face to the bottom face.

11. The LED chip unit of claim 10, wherein the current baffles are located between the electrical-conductive posts.

12. The LED chip unit of claim 11, wherein the current baffles and the electrical-conductive posts are alternately placed.

13. The LED chip unit of claim 10, wherein the second electrical pad covers and directly connects to the electrical-conductive posts.

14. The LED chip unit of claim 5, wherein the current baffles are depressions.

15. The LED chip unit of claim 14, wherein the depressions are void with air contained therein.

16. The LED chip unit of claim 14, wherein the depressions are defined in a bottom face of the substrate.

17. The LED chip unit of claim 14, wherein the base is made of electrical-conductive material.

18. The LED chip unit of claim 17, wherein the first electrical pad is insulated from the base by an insulative layer formed therebetween.
